(19) United States
(12) Patent Application Publication
(10) Pub. No.: US 2025/0287740 A1
(43) Pub. Date: Sep. 11, 2025

(54) ANCHORED ENCAPSULATION IN LED DEVICES

(71) Applicant: CreeLED, Inc., Durham, NC (US)

(72) Inventors: Robert David Schmidt, Wake Forest, NC (US); Joseph M. Favale, JR., Cary, NC (US)

(21) Appl. No.: 18/597,406

(22) Filed: Mar. 6, 2024

(51) Int. Cl. H01L 33/48; H01L 33/54; H01L 33/62

(52) U.S. Cl. CPC H10H 20/8506; H10H 20/853; H10H 20/857

(57) ABSTRACT

Light-emitting diode (LED) devices and more particularly anchored encapsulation in LED packages and related structures is disclosed. Anchoring structures are described herein that improve adhesion with encapsulant materials. Exemplary LED packages include support structures with recesses and one or more anchoring structures integrated along recess sidewalls, thereby increasing surface areas of the recess sidewalls. When encapsulant materials are provided within the recesses, portions of encapsulant materials may conform to the anchoring structures to promote increased contact area between the encapsulant materials and the support structures. Exemplary support structures include lead frame structures with housings that form the recesses or submount structures.

### FIELD OF THE DISCLOSURE

The present disclosure relates to light-emitting diode (LED) devices and more particularly to anchored encapsulation in LED packages and related structures.

### BACKGROUND

Solid-state lighting devices such as light-emitting diodes (LEDs) are increasingly used in both consumer and commercial applications. Advancements in LED technology have resulted in highly efficient and mechanically robust light sources with a long service life. Accordingly, modern LEDs have enabled a variety of new display applications and are being increasingly utilized for general illumination applications, often replacing incandescent and fluorescent light sources.

LEDs are solid-state devices that convert electrical energy to light and generally include one or more active layers of semiconductor material (or an active region) arranged between oppositely doped n-type and p-type layers. When a bias is applied across the doped layers, holes and electrons are injected into the one or more active layers where they recombine to generate emissions such as visible light or ultraviolet emissions. An LED chip typically includes an active region that may be fabricated, for example, from gallium nitride, gallium phosphide, aluminum nitride, indium nitride, gallium-indium-based materials, gallium arsenide-based materials, and/or from organic semiconductor materials. Photons generated by the active region are initiated in all directions.

LED packages have been developed that can provide mechanical support, electrical connections, and encapsulation for LED emitters. Lumiphoric materials, such as phosphors, may also be arranged in close proximity to LED emitters to convert portions of light emissions to different wavelengths. As LED technology continues to be developed for ever-evolving modern applications, challenges exist in keeping up with operating demands for LED packages and related elements of LED packages.

The art continues to seek improved LEDs and solid-state lighting devices having desirable illumination characteristics capable of overcoming challenges associated with conventional lighting devices.

### SUMMARY

The present disclosure relates to light-emitting diode (LED) devices and more particularly to anchored encapsulation in LED packages and related structures. Anchoring structures are described herein that improve adhesion with encapsulant materials. Exemplary LED packages include support structures with recesses and one or more anchoring structures integrated along recess sidewalls, thereby increasing surface areas of the recess sidewalls. When encapsulant materials are provided within the recesses, portions of encapsulant materials may conform to the anchoring structures to promote increased contact area between the encapsulant materials and the support structures. Exemplary support structures include lead frame structures with housings that form the recesses or submount structures.

In one aspect, an LED package comprises: a support structure forming a recess with at least one recess sidewall; one or more LED chips within the recess; an encapsulant within the recess and over the one or more LED chips; and at least one anchoring structure integral with the at least one recess sidewall such that a portion of the encapsulant extends into the support structure at the at least one anchoring structure. In certain embodiments, the at least one anchoring structure is continuously arranged to form a ring along the at least one recess sidewall. In certain embodiments, the at least one anchoring structure is arranged in one or more segments along one or more portions of the at least one recess sidewall. In certain embodiments, the one or more segments of the at least one anchoring structure do not extend to corners of the recess. In certain embodiments, the at least one anchoring structure forms an indentation in the at least one recess sidewall and the indentation forms a rounded bottom. In certain embodiments, the at least one anchoring structure forms a well that extends into the at least one recess sidewall. In certain embodiments, the at least one anchoring structure forms an array of indentations along the at least one recess sidewall. In certain embodiments, the at least one anchoring structure comprises a textured surface of the at least one recess sidewall. In certain embodiments, the support structure comprises a lead frame structure with a housing, and the recess is formed within the housing.

In another aspect, a lead frame structure comprises: a lead frame; a housing molded to the lead frame, the housing forming a recess with at least one recess sidewall, a portion of the lead frame being accessible at a floor of the recess; and at least one anchoring structure integral with the housing, the at least one anchoring structure extending into the housing from the at least one recess sidewall. In certain embodiments, the at least one anchoring structure is continuously arranged to form a ring along the at least one recess sidewall. In certain embodiments, the at least one anchoring structure is arranged in one or more segments along one or more portions of the at least one recess sidewall. In certain embodiments, the at least one anchoring structure forms an indentation in the at least one recess sidewall and the indentation forms a rounded bottom. In certain embodiments, the at least one anchoring structure forms a well that extends into the at least one recess sidewall. In certain embodiments, the at least one anchoring structure forms an array of indentations along the at least one recess sidewall. In certain embodiments, the at least one anchoring structure comprises a textured surface of the at least one recess sidewall.

In another aspect, an LED display comprises: a display panel; and at least one LED package comprising: a support structure forming a recess with at least one recess sidewall; one or more LED chips within the recess; an encapsulant within the recess and over the one or more LED chips; and at least one anchoring structure integral with the at least one recess sidewall such that a portion of the encapsulant extends into the support structure at the at least one anchoring structure. In certain embodiments, the at least one anchoring structure forms one or more indentations in the at least one recess sidewall. In certain embodiments, the at least one anchoring structure forms a well that extends into the at least one recess sidewall. In certain embodiments, the at least one anchoring structure comprises a textured surface of the at least one recess sidewall.

In another aspect, any of the foregoing aspects individually or together, and/or various separate aspects and features as described herein, may be combined for additional advantage. Any of the various features and elements as disclosed herein may be combined with one or more other disclosed features and elements unless indicated to the contrary herein.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1A is a top view of a light-emitting diode (LED) package with multiple LED chips according to principles of the present disclosure.

FIG. 1B is a top perspective view of the LED package of FIG. 1A with the LED chips omitted for illustrative purposes.

FIG. 1C is a cross-section of the LED package of FIG. 1A taken along the line 1C-1C of FIG. 1A with an exploded view of the recess sidewalls.

FIG. 2A is a top view of an LED package that is similar to the LED package of FIGS. 1A to 1C for embodiments where anchoring structures are formed in a discontinuous manner along the recess sidewalls.

FIG. 2B is a top perspective view of the LED package of FIG. 2A with the LED chips omitted for illustrative purposes.

FIG. 2C is a cross-section of the LED package of FIG. 2A taken along the line 2C-2C of FIG. 2A with an exploded view of the recess sidewalls.

FIG. 3A is a top view of an LED package that is similar to the LED package of FIGS. 2A to 2C for embodiments where the anchoring structures are formed as an array of boreholes in the recess sidewalls.

FIG. 3B is a top perspective view of the LED package of FIG. 3A with the LED chips omitted for illustrative purposes.

FIG. 3C is a cross-section of the LED package of FIG. 3A taken along the line 3C-3C of FIG. 3A with an exploded view of the recess sidewalls.

FIG. 4A is a top view of an LED package that is similar to the LED package of FIGS. 3A to 3C for embodiments where the anchoring structures are formed as an array of shallower indentations in the recess sidewalls.

FIG. 4B is a top perspective view of the LED package of FIG. 4A with the LED chips omitted for illustrative purposes.

FIG. 4C is a cross-section of the LED package of FIG. 4A taken along the line 4C-4C of FIG. 4A with an exploded view of the recess sidewalls.

FIG. 5 is a cross-section of an LED package that is similar to the LED package of FIGS. 4A to 4C for embodiments where the anchoring structure is in the form of a textured surface along the recess sidewalls.

FIG. 6 is a schematic diagram of a portion of an LED display with one or more LED packages according to principles of the present disclosure.

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

Embodiments are described herein with reference to schematic illustrations of embodiments of the disclosure. As such, the actual dimensions of the layers and elements can be different, and variations from the shapes of the illustrations as a result, for example, of manufacturing techniques and/or tolerances, are expected. For example, a region illustrated or described as square or rectangular can have rounded or curved features, and regions shown as straight lines may have some irregularity. Thus, the regions illustrated in the figures are schematic and their shapes are not intended to illustrate the precise shape of a region of a device and are not intended to limit the scope of the disclosure. Additionally, sizes of structures or regions may be exaggerated relative to other structures or regions for illustrative purposes and, thus, are provided to illustrate the general structures of the present subject matter and may or may not be drawn to scale. Common elements between figures may be shown herein with common element numbers and may not be subsequently re-described.

The present disclosure relates to light-emitting diode (LED) devices and more particularly to anchored encapsulation in LED packages and related structures. Anchoring structures are described herein that improve adhesion with encapsulant materials. Exemplary LED packages include support structures with recesses and one or more anchoring structures integrated along recess sidewalls, thereby increasing surface areas of the recess sidewalls. When encapsulant materials are provided within the recesses, portions of encapsulant materials may conform to the anchoring structures to promote increased contact area between the encapsulant materials and the support structures. Exemplary support structures include lead frame structures with housings that form the recesses or submount structures.

Before delving into specific details of various aspects of the present disclosure, an overview of various elements that may be included in exemplary LED packages of the present disclosure is provided for context. An LED chip typically comprises an active LED structure or region that can have many different semiconductor layers arranged in different ways. The fabrication and operation of LEDs and their active structures are generally known in the art and are only briefly discussed herein. The layers of the active LED structure can be fabricated using known processes with a suitable process being fabrication using metal organic chemical vapor deposition. The layers of the active LED structure can comprise many different layers and generally comprise an active layer sandwiched between n-type and p-type oppositely doped epitaxial layers, all of which are formed successively on a growth substrate. It is understood that additional layers and elements can also be included in the active LED structure, including, but not limited to, buffer layers, nucleation layers, super lattice structures, undoped layers, cladding layers, contact layers, and current-spreading layers and light extraction layers and elements. The active layer can comprise a single quantum well, a multiple quantum well, a double heterostructure, or super lattice structures.

The active LED structure can be fabricated from different material systems, with some material systems being Group III nitride-based material systems. Group III nitrides refer to those semiconductor compounds formed between nitrogen (N) and the elements in Group III of the periodic table, usually aluminum (Al), gallium (Ga), and indium (In). Gallium nitride (GaN) is a common binary compound. Group III nitrides also refer to ternary and quaternary compounds such as aluminum gallium nitride (AlGaN), indium gallium nitride (InGaN), and aluminum indium gallium nitride (AlInGaN). For Group III nitrides, silicon (Si) is a common n-type dopant and magnesium (Mg) is a common p-type dopant. Accordingly, the active layer, n-type layer, and p-type layer may include one or more layers of GaN, AlGaN, InGaN, and AlInGaN that are either undoped or doped with Si or Mg for a material system based on Group III nitrides. Other material systems include organic semiconductor materials, and other Group III-V systems such as gallium phosphide (GaP), gallium arsenide (GaAs), and related compounds.

The active LED structure may be grown on a growth substrate that can include many materials, such as sapphire, SiC, silicon, aluminum nitride (AlN), and GaN. Sapphire is a common substrate for Group III nitrides and also has certain advantages, including being lower cost, having established manufacturing processes, and having good light-transmissive optical properties, among other related substrates.

Different embodiments of the active LED structure can emit different wavelengths of light depending on the composition of the active layer. In some embodiments, the active LED structure emits blue light with a peak wavelength range of approximately 430 nanometers (nm) to 480 nm. In other embodiments, the active LED structure emits green light with a peak wavelength range of 500 nm to 570 nm. In other embodiments, the active LED structure emits red light with a peak wavelength range of 600 nm to 700 nm. In certain embodiments, the active LED structure may be configured to emit light that is outside the visible spectrum, including one or more portions of the ultraviolet (UV) spectrum, or one or more portions of the near infrared spectrum, and/or the infrared spectrum (e.g., 700 nm to 1000 nm). The UV spectrum is typically divided into three wavelength range categories denotated with letters A, B, and C. In this manner, UV-A light is typically defined as a peak wavelength range from 315 nm to 400 nm, UV-B is typically defined as a peak wavelength range from 280 nm to 315 nm, and UV-C is typically defined as a peak wavelength range from 100 nm to 280 nm. UV LEDs are of particular interest for use in applications related to the disinfection of microorganisms in air, water, and surfaces, among others. In other applications, UV LEDs may also be provided with one or more lumiphoric materials to provide LED packages with aggregated emissions having a broad spectrum and improved color quality for visible light applications.

An LED chip can also be covered with one or more lumiphoric materials (also referred to herein as lumiphors), such as phosphors, such that at least some of the light from the LED chip is absorbed by the one or more lumiphors and is converted to one or more different wavelength spectra according to the characteristic emission from the one or more lumiphors. In this regard, at least one lumiphor receiving at least a portion of the light generated by the LED source may re-emit light having different peak wavelength than the LED source. An LED source and one or more lumiphoric materials may be selected such that their combined output results in light with one or more desired characteristics such as color, color point, intensity, etc. In certain embodiments, aggregate emissions of LED chips, optionally in combination with one or more lumiphoric materials, may be arranged to provide cool white, neutral white, or warm white light, such as within a color temperature range of 2,500 Kelvin (K) to 10,000 K. In certain embodiments, lumiphoric materials having cyan, green, amber, yellow, orange, and/or red peak emission wavelengths may be used. In some embodiments, the combination of the LED chip and the one or more lumiphors (e.g., phosphors) emits a generally white combination of light. The one or more phosphors may include yellow (e.g., YAG:Ce), green (e.g., LuAg:Ce), and red (e.g., Ca_{i-x-y}SrₓEu_{y}AlSiN₃) emitting phosphors, and combinations thereof.

Lumiphoric materials as described herein may be or include one or more of a phosphor, a scintillator, a lumiphoric ink, a quantum dot material, a day glow tape, and the like. Lumiphoric materials may be provided by any suitable means, for example, direct coating on one or more surfaces of an LED, dispersal in an encapsulant material configured to cover one or more LEDs, and/or coating on one or more optical or support elements (e.g., by powder coating, inkjet printing, or the like). In certain embodiments, lumiphoric materials may be downconverting or upconverting, and combinations of both downconverting and upconverting materials may be provided. In certain embodiments, multiple different (e.g., compositionally different) lumiphoric materials arranged to produce different peak wavelengths may be arranged to receive emissions from one or more LED chips. One or more lumiphoric materials may be provided on one or more portions of an LED chip in various configurations. In certain embodiments, lumiphoric materials may be provided over one or more surfaces of LED chips, while other surfaces of such LED chips may be devoid of lumiphoric material.

As used herein, a layer or region of a light-emitting device may be considered to be “transparent” when at least 80% of emitted radiation that impinges on the layer or region emerges through the layer or region. Moreover, as used herein, a layer or region of an LED is considered to be “reflective” or embody a “mirror” or a “reflector” when at least 80% of the emitted radiation that impinges on the layer or region is reflected. In some embodiments, the emitted radiation comprises visible light such as blue and/or green LEDs with or without lumiphoric materials. In other embodiments, the emitted radiation may comprise nonvisible light. For example, in the context of GaN-based blue and/or green LEDs, silver (Ag) may be considered a reflective material (e.g., at least 80% reflective). In the case of UV LEDs, appropriate materials may be selected to provide a desired, and in some embodiments high, reflectivity and/or a desired, and in some embodiments low, absorption. In certain embodiments, a “light-transmissive” material may be configured to transmit at least 50% of emitted radiation of a desired wavelength.

The present disclosure can be useful for LED chips having a variety of geometries, such as vertical geometry or lateral geometry. A vertical geometry LED chip typically includes anode and cathode connections on opposing sides or faces of the LED chip. A lateral geometry LED chip typically includes both anode and cathode connections on the same side of the LED chip that is opposite a substrate, such as a growth substrate. In certain embodiments, a lateral geometry LED chip may be mounted on a submount of an LED package such that the anode and cathode connections are on a face of the LED chip that is opposite the submount. In this configuration, wire bonds may be used to provide electrical connections with the anode and cathode connections. In other embodiments, a lateral geometry LED chip may be flip-chip mounted on a surface of a submount of an LED package such that the anode and cathode connections are on a face of the active LED structure that is adjacent to the submount. In this configuration, electrical traces or patterns may be provided on the submount for providing electrical connections to the anode and cathode connections of the LED chip. In a flip-chip configuration, the active LED structure is configured between the substrate of the LED chip and the submount for the LED package. Accordingly, light emitted from the active LED structure may pass through the substrate in a desired emission direction. In other embodiments, an active LED structure may be bonded to a carrier submount, and the growth substrate may be removed such that light may exit the active LED structure without passing through the growth substrate.

According to aspects of the present disclosure, LED packages may include one or more elements, such as lumiphoric materials, encapsulants, light-altering materials, lenses, and electrical contacts, among others that are provided with one or more LED chips. In certain aspects, an LED package may include a support member, such as a submount or a lead frame. Suitable materials for the submount include, but are not limited to, ceramic materials such as aluminum oxide or alumina, AlN, or organic insulators like polyimide (PI) and polyphthalamide (PPA). In other embodiments, a submount may comprise a printed circuit board (PCB), sapphire, Si or any other suitable material. For PCB embodiments, different PCB types can be used such as standard FR-4 PCB, metal core PCB, or any other type of PCB. In still further embodiments, the support structure may embody a lead frame structure. Light-altering materials may be arranged within LED packages to reflect or otherwise redirect light from the one or more LED chips in a desired emission direction or pattern.

In certain embodiments, aspects of the present disclosure relate to LED packages with lead frame structures that are at least partially encased by a body or housing. A lead frame structure may typically be formed of a metal, such as copper, copper alloys, or other conductive metals. The lead frame structure may initially be part of a larger metal structure that is singulated during manufacturing of individual LED packages. Within an individual LED package, isolated portions of the lead frame structure may form anode and cathode connections for an LED chip. The body or housing may be formed of an insulating material that is arranged to surround or encase portions of the lead frame structure. For example, the body or housing may comprise one or more of PPA, PCT, EMC, FR4, BT, impregnated fiber, and/or plastics, etc. The housing may be formed on the lead frame structure before singulation so that the individual lead frame portions may be electrically isolated from one another and mechanically supported by the housing within an individual LED package. The housing may form a cup or a recess in which one or more LED chips may be mounted to the lead frame at a floor of the recess. Portions of the lead frame structure may extend from the recess and through the housing to protrude or be accessible outside of the housing to provide external electrical connections. An encapsulant material, such as silicone, epoxy, or polymethyl methacrylate (PMMA), among others, may fill the recess to encapsulate the one or more LED chips. In certain embodiments, one or more lumiphoric materials, such as phosphor particles, may be integrated or otherwise embedded within the encapsulant material.

In conventional LED packages, adhesion between the encapsulant material and sidewalls of the recess can be compromised by thermal and/or physical stresses during operation, particularly for LED packages in outdoor environments. In some instances, delamination of the encapsulant along the sidewalls of the recess may occur, thereby allowing moisture ingress pathways into the LED package.

According to aspects of the present disclosure, improved anchoring of the encapsulant material within the LED package is provided by anchoring structures arranged along recess sidewalls. The anchoring structures may form nonplanar surface relative to the recess sidewalls that effectively increase surface areas of the recess sidewalls. When the encapsulant material is formed within the recess, portions of the encapsulant material may conform to anchoring structures to provide increased contact area between the encapsulant material and the housing of the LED package. In this regard, anchoring structures as disclosed herein may decrease rates of encapsulant delamination from recess sidewalls. Accordingly, anchoring structures of the present disclosure may build on outdoor water ingress protection in outdoor packages, while minimizing physical stresses on interior components by mitigating separation-induced physical stress, such as pulling or flexing of wire bonds and chip adhesion. Additionally, certain embodiments may reduce inconsistency of applied optic positioning resulting in large far field emission ranges.

In certain embodiments, anchoring structures may be formed to extend into the body or housing of LED packages, for example as one or more openings that extend into the housing from the surface of the recess sidewalls. When the encapsulant is provided within the recess, the encapsulant may fill the openings within the housing such that portions of the encapsulant extend past the recess sidewalls and into the housing. The anchoring structures may form various shapes, such as notches, indentations, boreholes, wells, channels, grooves, dots, and texturing, among other features. Anchoring structures may be spaced apart in a discontinuous manner along portions of a package housing. In other embodiments, one or more anchoring structures may be arranged in a continuous manner along the recess sidewalls, including around an entire perimeter of recess sidewalls. Anchoring structures may form a pattern along recess sidewalls, such as an array of nodules or indentations, or anchoring structures may form a randomly textured surface. Patterns may include arrays of anchoring structures and/or a sawtooth pattern. Randomly textured surfaces may be arranged on a micro scale that is below manufacturing capabilities for molding processes, such as with feature sizes at or below about 50 microns (μm), or no more than 25 μm, or no more than 2 μm.

Anchoring structures as disclosed herein may be formed in portions of package housings by various techniques, including custom injection molding, laser engraving, and etched injection molding with texture that can still release. In certain embodiments, anchoring structures may be formed after housings are molded by one or more of etching, grinding, cutting, and/or grooving.

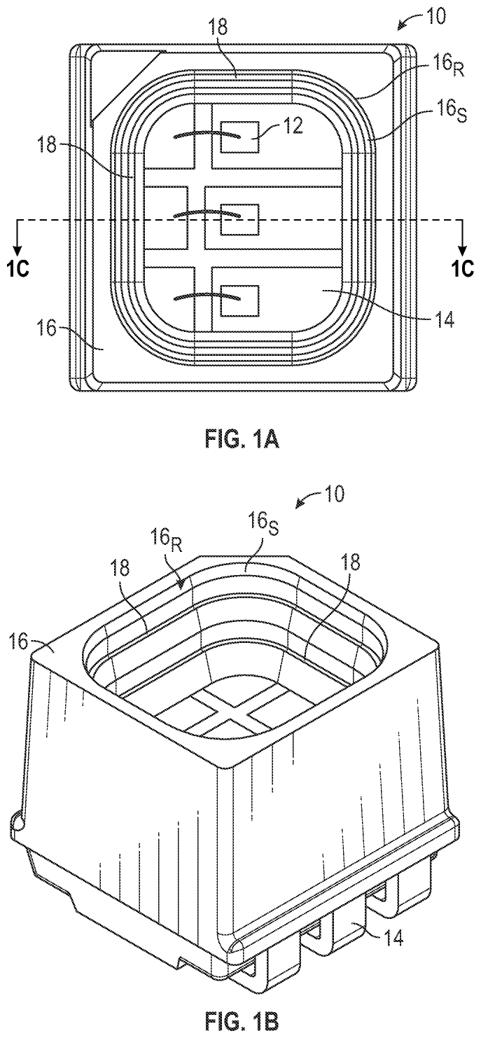

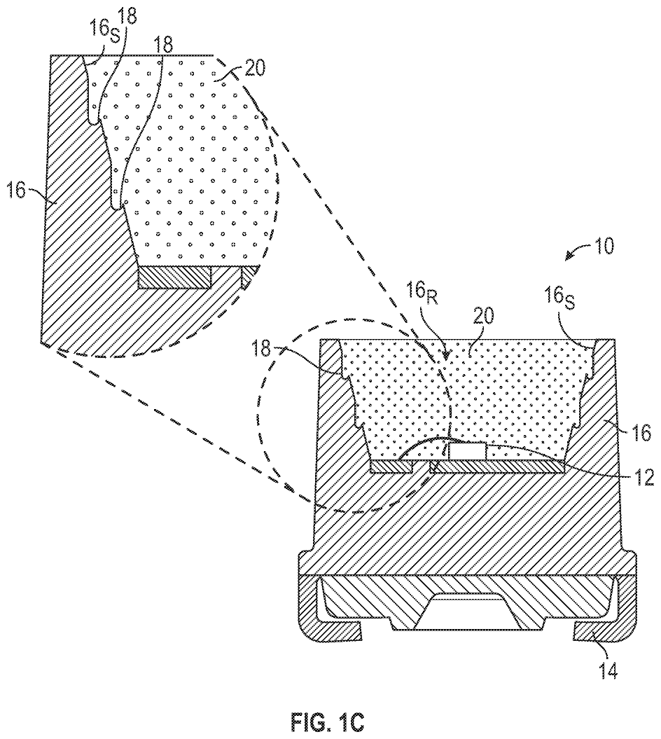

FIG. 1A is a top view of an LED package 10 with multiple LED chips 12 according to principles of the present disclosure. FIG. 1B is a top perspective view of the LED package 10 of FIG. 1A with the LED chips 12 omitted for illustrative purposes. The LED chips 12 may be configured to all emit a same emission color, or the LED chips 12 may be configured to emit different emission colors, such as red, green, and blue peak wavelengths. In FIG. 1A, the LED package 10 is a lead frame package that includes a lead frame structure 14 within a housing 16. The LED chips 12 are within a recess 16R of the housing 16 and are mounted and/or electrically coupled to portions of the lead frame structure 14 exposed at a bottom or floor of the recess 16R. In FIG. 1A, each LED chip 12 is mounted and electrically coupled to a lead of the lead frame structure 14 and electrically coupled to a corresponding lead by way of a wire bond. However, other electrical connections are possible, such as lateral LED chip structures where two wire bonds are coupled to opposing leads or flip-chip structures that do not require wire bonds. In this manner, each LED chip 12 is electrically coupled to an anode lead and a corresponding cathode lead of the lead frame structure 14. As illustrated in FIGS. 1A and 1B, sidewalls 16_{S} of the recess 16_{R} include one or more anchoring structures 18. By way of example, two anchoring structures 18 are provided along different lateral positions of the sidewalls 16_{S}. As illustrated, the recess sidewalls 16_{S} may form angled surfaces that taper inward toward the LED chips 12. In FIGS. 1A and 1B, each of the anchoring structures 18 is arranged to extend continuously along the sidewalls 16_{S}. In this manner, the anchoring structures 18 may form continuous rings along the sidewalls 16_{S}.

FIG. 1C is a cross-section of the LED package 10 of FIG. 1A taken along the line 1C-1C of FIG. 1A with an exploded view of the recess sidewalls 16_{S}. In FIG. 1C, an encapsulant 20 is provided within the recess 16_{R} and over the LED chips 12. As illustrated, the anchoring structures 18 form features with one or more surfaces that are nonplanar with respect to the sidewalls 16_{S} to effectively break up the planar surface of the recess sidewalls 16_{S}. By way of example, each anchoring structure 18 in FIG. 1C forms an indentation with a rounded bottom. In this manner, when the encapsulant 20 is provided within the recess 16_{R}, the encapsulant 20 may conform and/or be in contact with surfaces of the anchoring structures 18 to improve adhesion with the housing 16. The rounded bottom of the anchoring structures 18 may advantageously avoid sharp corners or edges for improved filling of the encapsulant 20.

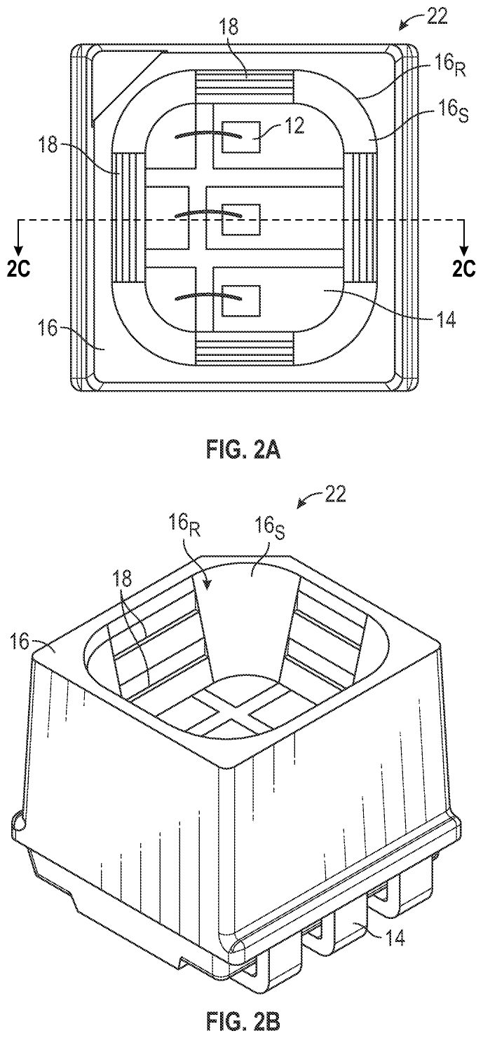

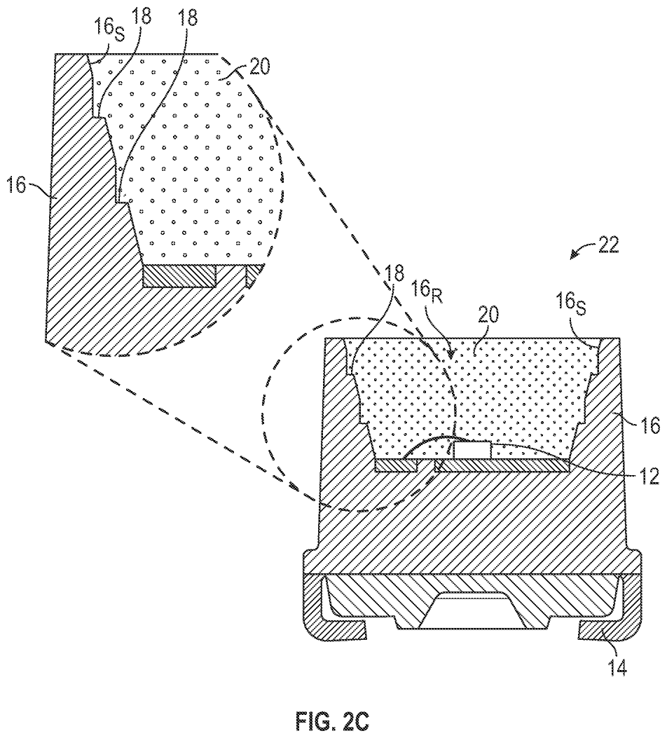

FIG. 2A is a top view of an LED package 22 that is similar to the LED package 10 of FIGS. 1A to 1C for embodiments where the anchoring structures 18 are formed in a discontinuous manner along the recess sidewalls 16_{S}. FIG. 2B is a top perspective view of the LED package 22 of FIG. 2A with the LED chips 12 omitted for illustrative purposes. As illustrated, the anchoring structures 18 are arranged to extend in one or more segments along the recess sidewalls 16_{S}. By way of example, the anchoring structures 18 may extend on opposing sides of the recess 16_{R} but not in corners thereof. In this manner, corner sections of the recess 16_{R} may be more easily filled with the encapsulant (e.g., 20 of FIG. 2C) while improved adhesion is provided by the anchoring structures 18. FIG. 2C is a cross-section of the LED package 22 of FIG. 2A taken along the line 2C-2C of FIG. 2A with an exploded view of the recess sidewalls 16_{S}. As illustrated, the anchoring structures 18 form features with one or more surfaces that are nonplanar with respect to the sidewalls 16_{S} to effectively break up the planar surface of the recess sidewalls 16_{S}. By way of example, each anchoring structure 18 in FIG. 2C forms an indentation with a squared bottom. In certain embodiments, such a shape may be more easily molded concurrently with molding of the housing 16. In other embodiments, the shape may be formed in whole or in part through post-mold processing.

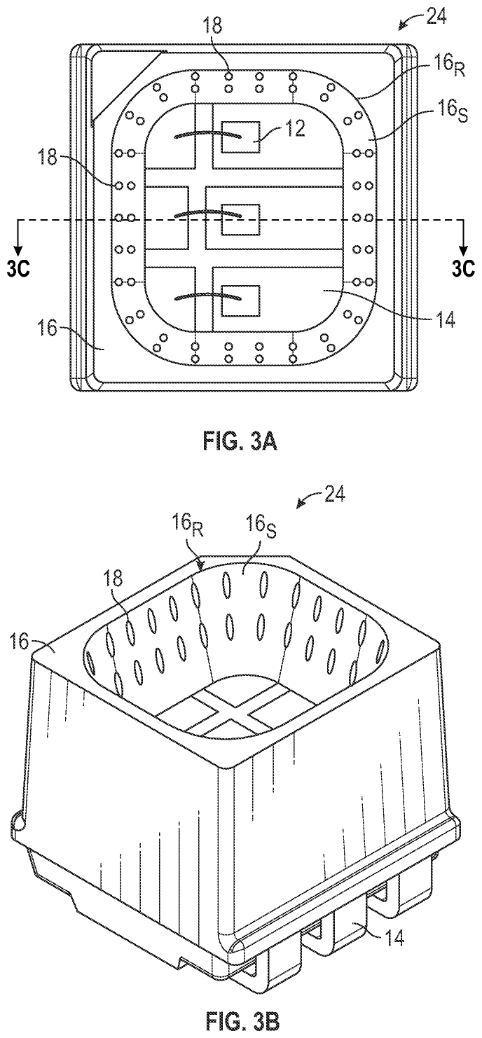

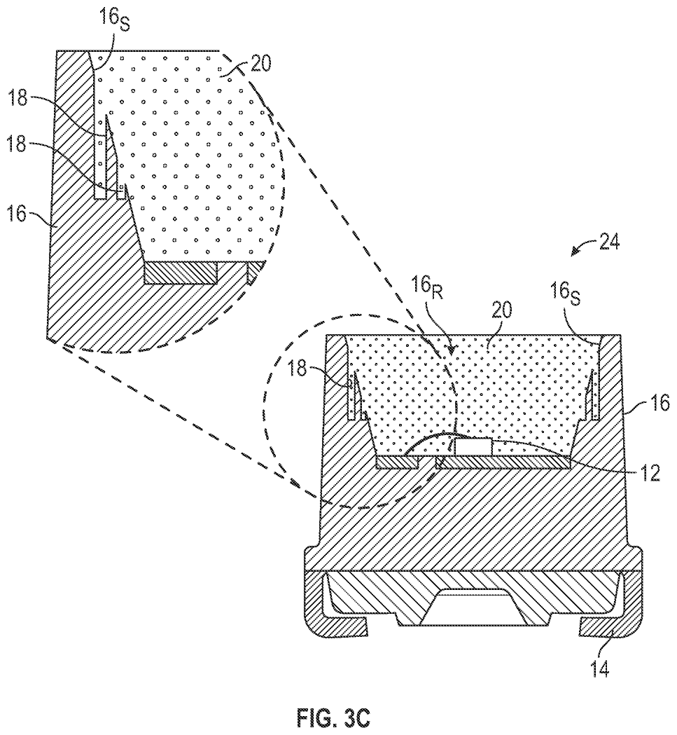

FIG. 3A is a top view of an LED package 24 that is similar to the LED package 22 of FIGS. 2A to 2C for embodiments where the anchoring structures 18 are formed as an array of boreholes in the recess sidewalls 16_{S}. FIG. 3B is a top perspective view of the LED package 24 of FIG. 3A with the LED chips 12 omitted for illustrative purposes. As illustrated, the anchoring structures 18 are arranged in an array of boreholes along the recess sidewalls 16_{S}. In certain embodiments, the anchoring structures 18 may form one or more rings of spaced-apart boreholes along the recess sidewalls 16_{S}. FIG. 3C is a cross-section of the LED package 24 of FIG. 3A taken along the line 3C-3C of FIG. 3A with an exploded view of the recess sidewalls 16_{S}. As illustrated, the anchoring structures 18 form borehole features that extend into to the sidewalls 16_{S} to effectively break up the planar surface of the recess sidewalls 16_{S}. By way of example, the borehole of each anchoring structure 18 in FIG. 3C is arranged in a vertical manner, although the boreholes could extend in angled directions within the housing 16. As illustrated, each anchoring structure 18 effectively forms a well within the housing 16 for the encapsulant 20. Accordingly, the encapsulant 20 may fill each anchoring structure 18 deeper into the housing 16 for improved adhesion. Additionally, if any moisture ingress were to take place between the encapsulant 20 and the sidewalls 16_{S}, the moisture would have an even longer path to travel before reaching the lead frame structure 14 or the LED chips 12. In certain aspects, the boreholes may even form traps or wells for moisture, thereby extending a lifetime of the LED package 24.

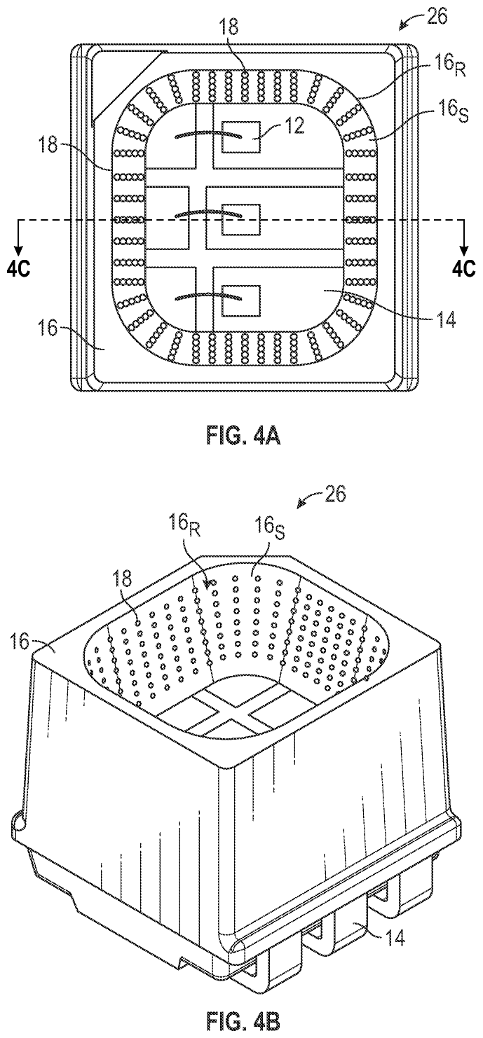

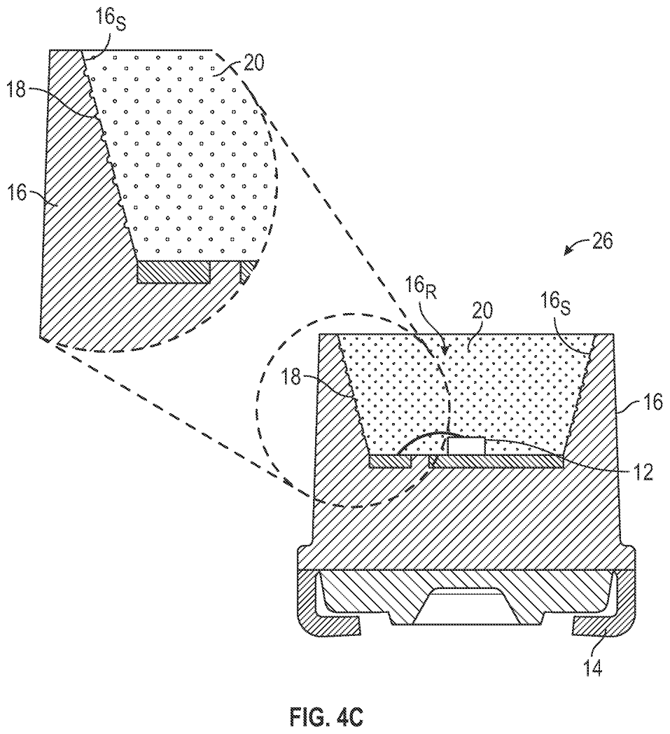

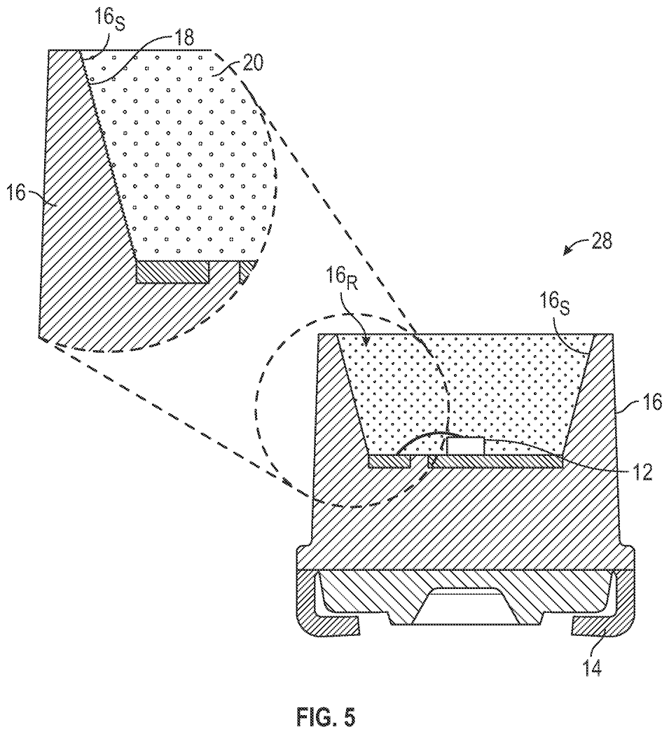

FIG. 4A is a top view of an LED package 26 that is similar to the LED package 24 of FIGS. 3A to 3C for embodiments where the anchoring structures 18 are formed as an array of shallower indentations in the recess sidewalls 16_{S}. FIG. 4B is a top perspective view of the LED package 26 of FIG. 4A with the LED chips 12 omitted for illustrative purposes. As illustrated, the anchoring structures 18 are arranged as an array of circular indentations along the recess sidewalls 16_{S}. Since the anchoring structures 18 are shallower features in the housing 16 than in FIGS. 3A to 3C, the anchoring structures 18 may be arranged across a larger surface area of the recess sidewalls 16_{S}. FIG. 4C is a cross-section of the LED package 26 of FIG. 4A taken along the line 4C-4C of FIG. 4A with an exploded view of the recess sidewalls 16_{S}. As illustrated, the anchoring structures 18 form the array of indentations that extend along a majority, or more than half, of a distance of the recess sidewalls 16_{S} in a direction from the top of the LED package 26 to the floor of the recess 16_{R}.

FIG. 5 is a cross-section of an LED package 28 that is similar to the LED package 26 of FIGS. 4A to 4C for embodiments where the anchoring structure 18 are in the form of a textured surface along the recess sidewalls 16_{S}. As illustrated in the exploded view in FIG. 5, the textured surface may form an irregular nonplanar surface to promote enhanced adhesion with the encapsulant 20. The textured surface may have irregular features on the microscale, such as at or below about 50 μm, or no more than 25 μm, or no more than 2 μm as described above.

By way of example, FIGS. 1A to 5 are described above in the context of lead frame structures. In any of the above-described LED packages of FIGS. 1A to 5, the described support structures may alternatively embody submount structures. In this manner, the housing 16 may be formed by a ceramic submount or a PCB with the recess 16_{R} and recess sidewalls 16_{S} being formed therein or with laminate structures that build up from mounting surfaces for LED chips.

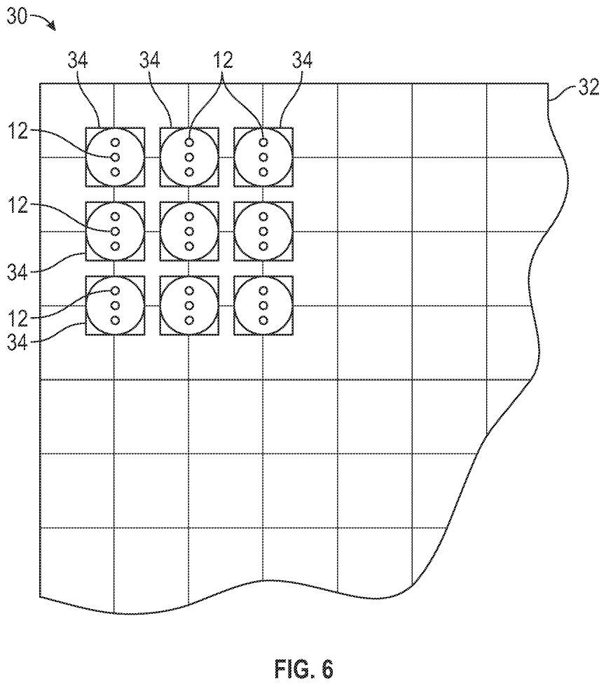

FIG. 6 is a schematic diagram of a portion of an LED display screen 30, that is, for example, an indoor and/or outdoor screen comprising, in general terms, a display panel including a driver PCB 32 carrying a large number of surface-mount devices (SMDs) 34 arranged in rows and columns, each SMD 34 defining a pixel. The SMDs 34 may comprise LED packages with LED chips 12 as described above for any of the embodiments shown in FIGS. 1A-5. The SMDs 34 are electrically connected to traces or pads on the PCB 32 to respond to appropriate electrical signal processing and driver circuitry (not shown). As disclosed above, it is to be appreciated that while FIG. 6 depicts the LED chips 12 in a linear arrangement, in other embodiments, the LED chips 12 may be arranged in different configurations. By forming anchoring structures for the SMDs 34 as described above for any of FIGS. 1A-5, encapsulants of the SMDs 34 may have increased stability with reduced delamination. Accordingly, the LED display screen 30 may exhibit improved reliability, reduced sensitivity to moisture ingress, and increased operating lifetime. Additionally, with improved anchoring, inconsistencies in emission patterns associated with encapsulant delamination may be reduced.

It is contemplated that any of the foregoing aspects, and/or various separate aspects and features as described herein, may be combined for additional advantage. Any of the various embodiments as disclosed herein may be combined with one or more other disclosed embodiments unless indicated to the contrary herein.

Those skilled in the art will recognize improvements and modifications to the preferred embodiments of the present disclosure. All such improvements and modifications are considered within the scope of the concepts disclosed herein and the claims that follow.

What is claimed is:

1. A light-emitting diode (LED) package comprising:
a support structure forming a recess with at least one recess sidewall;
one or more LED chips within the recess;
an encapsulant within the recess and over the one or more LED chips; and
at least one anchoring structure integral with the at least one recess sidewall such that a portion of the encapsulant extends into the support structure at the at least one anchoring structure.

2. The LED package of claim 1, wherein the at least one anchoring structure is continuously arranged to form a ring along the at least one recess sidewall.

3. The LED package of claim 1, wherein the at least one anchoring structure is arranged in one or more segments along one or more portions of the at least one recess sidewall.

4. The LED package of claim 3, wherein the one or more segments of the at least one anchoring structure do not extend to corners of the recess.

5. The LED package of claim 1, wherein the at least one anchoring structure forms an indentation in the at least one recess sidewall and the indentation forms a rounded bottom.

6. The LED package of claim 1, wherein the at least one anchoring structure forms a well that extends into the at least one recess sidewall.

7. The LED package of claim 1, wherein the at least one anchoring structure forms an array of indentations along the at least one recess sidewall.

8. The LED package of claim 1, wherein the at least one anchoring structure comprises a textured surface of the at least one recess sidewall.

9. The LED package of claim 1, wherein the support structure comprises a lead frame structure with a housing, and the recess is formed within the housing.

10. A lead frame structure comprising:
a lead frame;
a housing molded to the lead frame, the housing forming a recess with at least one recess sidewall, a portion of the lead frame being accessible at a floor of the recess; and
at least one anchoring structure integral with the housing, the at least one anchoring structure extending into the housing from the at least one recess sidewall.

11. The lead frame structure of claim 10, wherein the at least one anchoring structure is continuously arranged to form a ring along the at least one recess sidewall.

12. The lead frame structure of claim 10, wherein the at least one anchoring structure is arranged in one or more segments along one or more portions of the at least one recess sidewall.

13. The lead frame structure of claim 10, wherein the at least one anchoring structure forms an indentation in the at least one recess sidewall and the indentation forms a rounded bottom.

14. The lead frame structure of claim 10, wherein the at least one anchoring structure forms a well that extends into the at least one recess sidewall.

15. The lead frame structure of claim 10, wherein the at least one anchoring structure forms an array of indentations along the at least one recess sidewall.

16. The lead frame structure of claim 10, wherein the at least one anchoring structure comprises a textured surface of the at least one recess sidewall.

17. A light-emitting diode (LED) display comprising:
a display panel; and
at least one LED package comprising:
a support structure forming a recess with at least one recess sidewall;
one or more LED chips within the recess;
an encapsulant within the recess and over the one or more LED chips; and
at least one anchoring structure integral with the at least one recess sidewall such that a portion of the encapsulant extends into the support structure at the at least one anchoring structure.

18. The LED display of claim 17, wherein the at least one anchoring structure forms one or more indentations in the at least one recess sidewall.

19. The LED display of claim 17, wherein the at least one anchoring structure forms a well that extends into the at least one recess sidewall.

20. The LED display of claim 17, wherein the at least one anchoring structure comprises a textured surface of the at least one recess sidewall.
